(19) United States
(12) Patent Application Publication
(10) Pub. No.: US 2026/0243127 A1
(43) Pub. Date: Aug. 20, 2026

(54) System and Method for Wafer Level Hermetic Packaging of Optical Microelectromechanical System

(71) Applicant: SILICON LIGHT MACHINES CORPORATION, San Jose, CA (US)

(72) Inventors: Garrett Torok, Los Altos, CA (US); Alexander Payne, Ben Lommond, CA (US)

(73) Assignee: SILICON LIGHT MACHINES CORPORATION, San Jose, CA (US)

(21) Appl. No.: 19/538,720

(22) Filed: Feb. 12, 2026

Related U.S. Application Data
(60) Provisional application No. 63/760,582, filed on Feb. 19, 2025.

(51) Int. Cl. E06B 3/67; B81C 1/00; G02B 26/08; H10W 90/00

(52) U.S. Cl. CPC E06B 3/6715; B81C 1/00269; G02B 26/0841; H10W 90/734; B81C 2203/0118

(57) ABSTRACT

A wafer level package for an optical microelectromechanical system (MEMS), and method of forming the same are provided. Generally, the package includes a fused silica window overlying the optical MEMS, and a spacer interposed between the window and a surface of the substrate on which the optical MEMS is formed, the spacer laterally surrounding the optical MEMS. A first preform between an attachment-surface of the substrate and a first attachment-surface of the spacer, and a second preform between a second attachment-surface of the spacer and an attachment-surface of the window form a hermetically sealed cavity enclosing the optical MEMS. The spacer is a nickel-cobalt alloy having a coefficient of thermal expansion between that of the substrate and window, and has a cross-section to enable movement between the window and substrate due to differences in thermal expansion without compromising the hermetically sealed cavity.

### CROSS-REFERENCE TO RELATED APPLICATIONS

This application claims the benefit of priority under 35 U.S.C. 119(e) to U.S. Provisional Patent Application Ser. No. 63/760,582, filed February 19, 2025.

### TECHNICAL FIELD

The present invention relates generally to Micro-Electromechanical Systems (MEMS), and more particularly to hermetically sealed packages for optical MEMS and methods of forming the same.

### BACKGROUND

Optical Microelectromechanical systems (MEMS) are used in a number of applications including fiber-optic communications, printing, projection or display, additive manufacturing, and in metrology and inspection systems. One type of MEMS particularly useful in the aforementioned applications is a MEMS-based Spatial light modulators (SLMs). MEMS-based SLMs include a number of movable, reflective or transmissive micromechanical structures adapted to modulate light incident thereon in response to electrical signals from an integrated circuit (IC) or driver. Typically, the driver is integrally formed on a common substrate with the micromechanical structures of the MEMS-based SLM. The light can be modulated in intensity, phase, polarization or direction. Generally, the MEMS-based SLM is packaged after fabrication in a package that includes a transparent window or an optically active element, such as a lens, to protect the delicate micromechanical structures from damage.

One problem with conventionally packaged MEMS-based SLMs, is that a difference in a coefficient of thermal expansion (CTE) between the substrate on which the SLM is fabricated and materials of the package, in particular the transparent window or lens, often damages the SLM or comprises the package leading to degradation of performance of the SLM. Attempts to mitigate such damage by selecting materials for the package to match the CTE of the SLM substrate often results in a compromise of optical or mechanical properties of the window or lens, leading to in sub-optimal performance of the SLM. In particular, glass with a CTE close to that of the substrate is subject to striations during forming the window or susceptible to damage (scratches) during use, both of which can impair performance of the SLM.

Another problem with conventionally packaged MEMS-based SLMs is that sources of light modulated by the SLM, such as high power lasers, can volatilize contaminates and materials in the package, which then condense on surfaces of the micromechanical structures, reducing the performance and operating life of the SLM.

Finally, conventional methods for packaging optical MEMS is accomplished post dicing or singulation of the MEMS from a substrate on which it is fabricated, adding to a cost of the manufacture, and potentially reducing yield due to damage or contamination during packaging.

Accordingly, there is a need for a package and methods of packaging for optical MEMS that does not compromise the performance and operating life of the optical MEMS. It is further desirable that the packaging method does not reduce yield of working MEMS or increase cost.

### SUMMARY

A wafer level package for an optical microelectromechanical system (MEMS), and method of forming the same are provided. Generally, the package includes a fused silica, boron-silicate or sapphire window overlying the optical MEMS, and a spacer interposed between the window and a surface of the substrate on which the optical MEMS is formed, the spacer laterally surrounding the optical MEMS. A first preform between an attachment-surface of the substrate and a first attachment-surface of the spacer, and a second preform between a second attachment-surface of the spacer and an attachment-surface of the window form a hermetically sealed cavity enclosing the optical MEMS. The spacer is a nickel-cobalt alloy, such as Kovar^{TM}, having a coefficient of thermal expansion between that of the substrate and window. Optionally, the spacer has a lateral cross-section perpendicular to the surface of the substrate enabling lateral movement between the window and substrate to permit differences in thermal expansion between the window and substrate without compromising the hermetically sealed cavity.

In some embodiments, the spacer includes adhesion promoting layers on the first and second attachment-surfaces to facilitate bonding between the spacer and substrate, and the spacer and window to enable forming the hermetically sealed cavity.

The hermetically sealed cavity can be filled with a fill gas selected to facilitate thermal management of the optical MEMS and/or inhibit chemical reactions between optically active surfaces of the optical MEMS and materials of the MEMS package. Tthe fill gas can include a mixture of one or more of nitrogen, hydrogen and helium. For example the fill gas can be a forming gas including a mixture of 80% nitrogen, 10% hydrogen and 10% helium. Alternatively, the fill gas can consist of substantially 100% hydrogen, helium or a mixture of both. In some embodiments, the fill gas pressurizes the hermetically sealed cavity up to 60 pounds per square inch (PSI).

The spacer can be configured to position light transmissive surfaces of the window parallel to the surface of the substrate, or to provide an angle between the window and the surface of the substrate to reduce reflection from at least one of an upper or lower light transmissive surfaces of the window. For example the spacer can be configured to provide an angle of 5° between the window and the surface of the substrate.

Optionally, the window can further include an anti-reflective coating (ARC) on at least one of an upper or lower light transmissive surfaces of the window.

### BRIEF DESCRIPTION OF THE DRAWINGS

Embodiments of the invention will now be described, by way of example only, with reference to the accompanying schematic drawings in which corresponding reference symbols indicate corresponding parts. Further, the accompanying drawings, which are incorporated herein and form part of the specification, illustrate embodiments of the present invention, and, together with the description, further serve to explain the principles of the invention and to enable a person skilled in the relevant art(s) to make and use the invention.

FIG. 1A is a schematic block diagram illustrating an embodiment of a SLM including ribbon-type Microelectromechanical System (MEMS) based diffractors;

FIG. 1B is a schematic block diagram of a sectional side view of the portion of the SLM of FIG. 1A illustrating a single ribbon;

FIG. 2A is a schematic block diagram illustrating an embodiment of a MEMS based two-dimensional (2D) diffractor in a quiescent state;

FIG. 2B is a schematic block diagram illustrating an embodiment of the MEMS based 2D diffractor of FIG. 2A in a diffracted state;

FIG. 2C is a schematic block diagram illustrating a top view of the MEMS based 2D diffractor of FIGS. 2A and 2B;

FIG. 3 is a schematic block diagram of a top view of an SLM including a multi-pixel, linear array of MEMS based 2D diffractors, such as those shown in FIGS. 2A-2C;

FIG. 4A is a schematic block diagram of a top view of an embodiment of a wafer level package for an optical MEMS, including an optically transparent cover;

FIG. 4B is a schematic block diagram of a sectional side view of the wafer level package of FIG. 4A;

FIG. 5A is an exploded perspective view of another embodiment of a wafer level package for an optical MEMS, including an optically transparent cover;

FIG. 5B is a schematic block diagram of a sectional side view of the wafer level package of FIG. 5A;

FIG. 5C is a schematic block diagram of a sectional side view of another embodiment of the wafer level package of FIG. 5A, including a tilted window or optically transparent cover;

FIG. 6 is a flowchart of a method of fabricating a hermetically sealed wafer level package for optical MEMS, according to an embodiment of the present disclosure.

The features and advantages of embodiments of the present invention will become more apparent from the detailed description set forth below when taken in conjunction with the drawings. In the drawings, like reference numbers generally indicate identical, functionally similar, and/or structurally similar elements.

### DETAILED DESCRIPTION

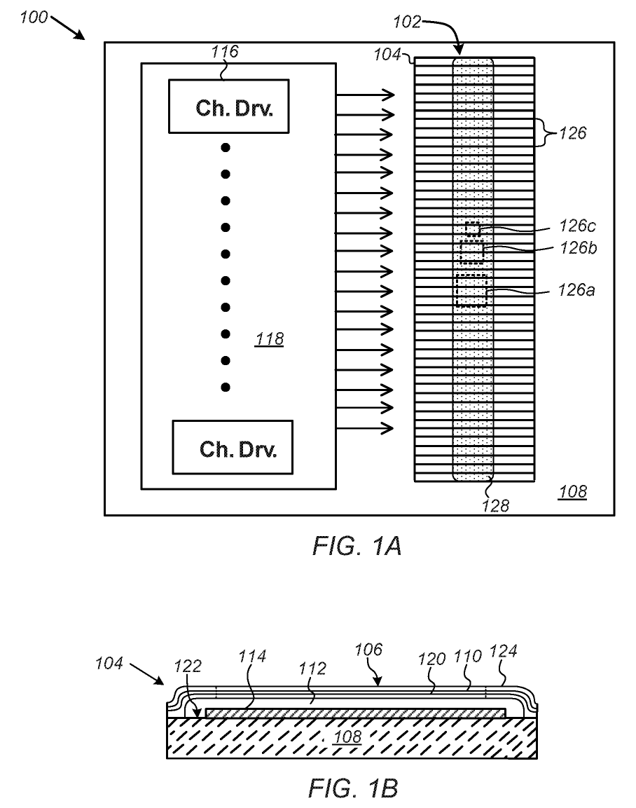

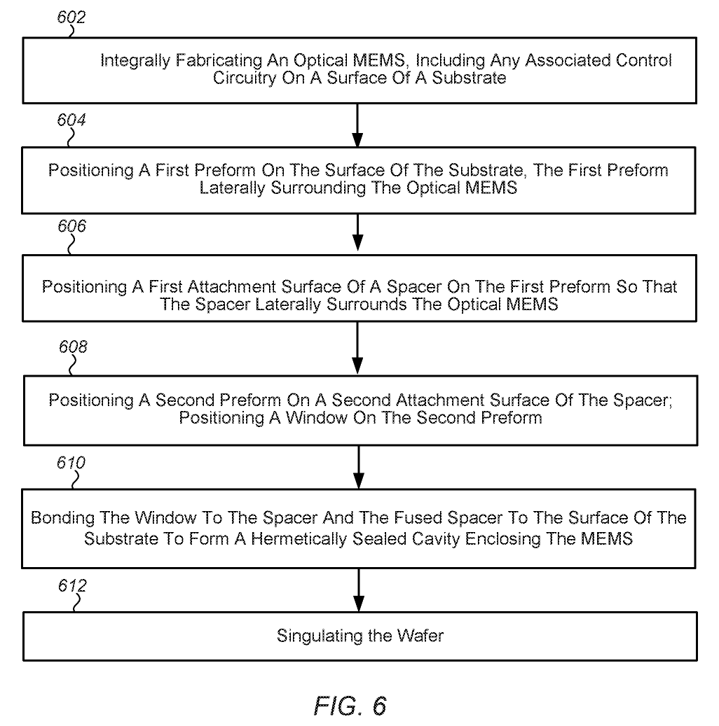

Embodiments of a wafer level microelectromechanical systems (MEMS) package for enclosing an optical MEMS and methods of forming the same will now be described with reference to the block diagrams of FIGS. 1A to 5C, and the flow chart of FIG. 6.

In the following description, numerous specific details are set forth, such as specific materials, dimensions and processes parameters etc. to provide a thorough understanding of the present invention. However, particular embodiments may be practiced without one or more of these specific details, or in combination with other known methods, materials, and apparatuses. In other instances, well-known semiconductor design and fabrication techniques have not been described in particular detail to avoid unnecessarily obscuring the present invention. Reference throughout this specification to "an embodiment" means that a particular feature, structure, material, or characteristic described in connection with the embodiment is included in at least one embodiment of the invention. Thus, the appearances of the phrase "in an embodiment" in various places throughout this specification are not necessarily referring to the same embodiment of the invention. Furthermore, the particular features, structures, materials, or characteristics may be combined in any suitable manner in one or more embodiments.

The terms "over," "under," "between," and "on" as used herein refer to a relative position of one layer with respect to other layers. As such, for example, one layer deposited or disposed over or under another layer may be directly in contact with the other layer or may have one or more intervening layers. Moreover, one layer deposited or disposed between layers may be directly in contact with the layers or may have one or more intervening layers. In contrast, a first layer "on" a second layer is in contact with that second layer. Additionally, the relative position of one layer with respect to other layers is provided assuming operations deposit, modify and remove films relative to a starting substrate without consideration of the absolute orientation of the substrate.

Briefly, the MEMS package includes a fused silica, boron-silicate or sapphire (Al₂O₃) window overlying the optical MEMS, and a spacer interposed between the window and a surface of the substrate on which the optical MEMS is formed, the spacer laterally surrounding the optical MEMS. A first preform between an attachment-surface of the substrate and a first attachment-surface of the spacer, and a second preform between a second attachment-surface of the spacer and an attachment-surface of the window form a hermetically sealed cavity enclosing the optical MEMS. The spacer is a nickel-cobalt alloy having a coefficient of thermal expansion between that of the substrate and window, and has a cross-section to enable movement between the window and substrate due to differences in thermal expansion without compromising the hermetically sealed cavity.

The optical MEMS can include a MEMS-based diffractive spatial light modulator (SLM). An embodiment of a SLM including a multi-pixel, linear array of MEMS based ribbon-type, electrostatically adjustable diffractors, such as a GLV^{TM} will now be described with reference to FIGS. 1A through 1B. For purposes of clarity, many of the details of SLMs in general and MEMS based ribbon-type diffractors in particular that are not relevant to the present invention have been omitted from the following description. The drawings described are only schematic and are non-limiting. In the drawings, the size of some of the elements may be exaggerated and not drawn to scale for illustrative purposes. The dimensions and the relative dimensions may not correspond to actual reductions to practice of the invention.

Referring to FIGS. 1A and 1B in the embodiment shown the SLM 100 includes a linear array 102 composed of thousands of free-standing, addressable electrostatically actuated ribbons 104, each ribbon having a light reflective surface 106 supported over a surface of a substrate 108, where a number of ribbons are grouped together to form the MEMS based diffractors. Each of the ribbons 104 includes an electrode 110 and is deflectable through a gap or cavity 112 toward the substrate 108 by electrostatic forces generated when a voltage is applied between the electrode 110 in the ribbon 104 and a base electrode 114 formed in or on the substrate. Each of the electrodes 110 are driven by one of a number of drive channels 116 in a driver 118, which may be integrally formed on the same substrate 108 with the linear array 102, as in the embodiment shown, or formed on a second substrate or chip and electrically coupled thereto (not shown).

A schematic sectional side view of a ribbon 104 of the SLM 100 of FIG. 1A is shown in FIG. 1B. Referring to FIG. 1B, the ribbon 104 includes an elastic mechanical layer 120 to support the ribbon above a surface 122 of the substrate 108, a conducting layer or electrode 110 and a reflective layer 124 including the reflective surface 106 overlying the mechanical layer and conducting layer.

Generally, the mechanical layer 120 comprises a taut silicon-nitride film, and is flexibly supported above the surface 122 of the substrate 108 by a number of posts or structures, typically also made of silicon-nitride, at both ends of the ribbon 104. The conducting layer or electrode 110 can be formed over and in direct physical contact with the mechanical layer 120, as shown, or underneath the mechanical layer. The conducting layer or electrode 110 can include any suitable conducting or semiconducting material compatible with standard MEMS fabrication technologies. For example, the conducting layer used for the electrode 110 can include a doped polycrystalline silicon (poly) layer, or a metal layer. Alternatively, if the reflective layer 124 is metallic it may also serve as the electrode 110.

The separate, discrete reflecting layer 124, where included, can include any suitable metallic, dielectric or semiconducting material compatible with standard MEMS fabrication technologies, and capable of being patterned using standard lithographic techniques to form the reflective surface 106.

In the embodiment shown, a number of ribbons are grouped together to form a large number of MEMS channels or pixels 126a-c, each driven by a much smaller number of drive channels 116. Deflection of a ribbon 104 causes light reflected from the reflective surface 106 to constructively or destructively interfere with light reflected from the reflective surface of an adjacent ribbon, there enabling the pixel 126 to switch between an on or bright state, an off or dark state or an intermediate gray-scale. In particular, it is noted that gray-scale control of the MEMS based diffractors can provide a precise dosage of light from each pixel onto the surface of the workpiece to compensate for non-uniformities in light illuminating the SLM 100 or in modulated transmitted from the SLM to a surface of a workpiece through imaging optics.

Referring to FIG. 1A in one embodiment suitable for laser marking systems, the linear array 102 includes 1088 individually addressable ribbons 104 that can be grouped together to form channels or pixels 126 having any number of ribbons depending on pixel size requirements. Additionally, the SLM can include drive channels 116 (shown in FIG. 1A) with up to 10-bit amplitude modulation to support gray-scale, and is capable of being modulated or switched at speeds up to 350 kHz. Referring again to FIG. 1A, shaded rectangle illustrates an illuminated area 128 on the linear array 102 illuminated by a rectangular beam directed onto the SLM 100. In some embodiments for laser marking systems, it is desirable to provide pixel configurations having a square aspect ratio. For example, in the embodiment shown wherein the linear array 102 includes about ribbons 104, each having a width of about 15 µm, and the illuminated area 128 has a width of about 75 µm, the ribbons can be grouped to form 360 square pixels 126a each including portions of three adjacent ribbons. Alternatively, the width of the illuminated area can be reduced to about 50 µm and the ribbons 104 can be grouped to form five hundred and 12 (512) 50 µm × 50 µm square pixels 126b each including portions of two adjacent ribbons, or the width of the illuminated area can be further reduced to about 15 µm such that each ribbon forms 1088 15 µm × 25 µm square pixels 126c.

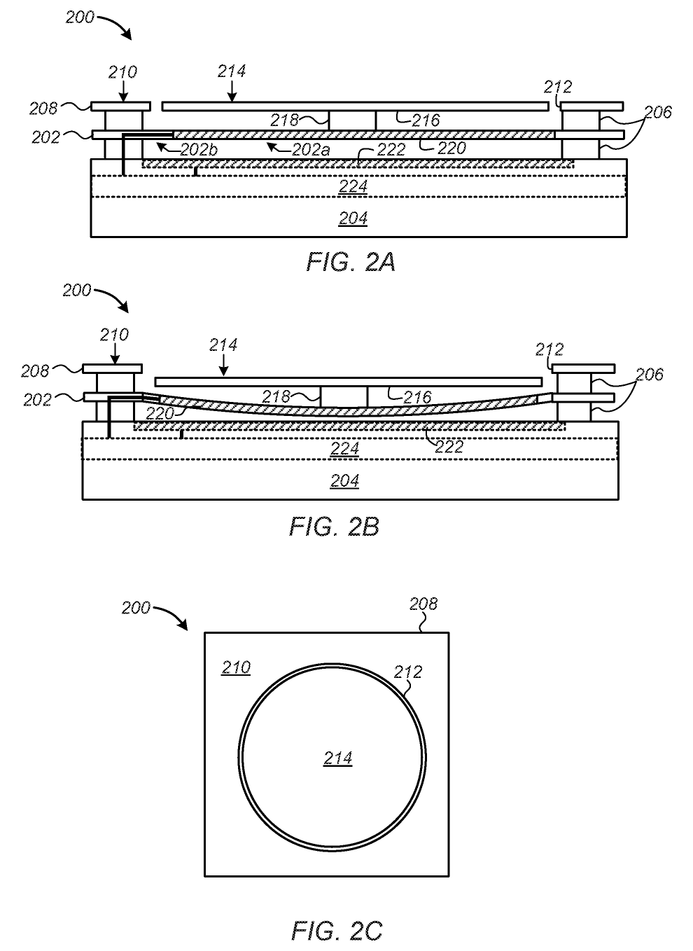

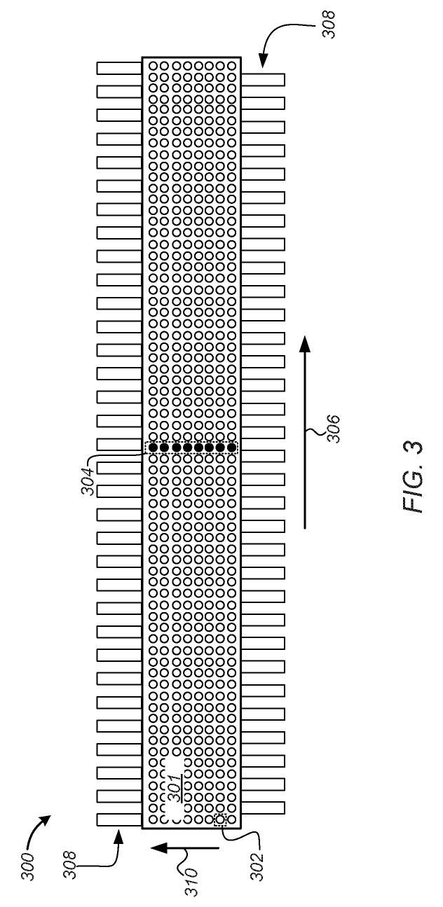

Another type of optical MEMS for which the wafer level package and packaging method of the present invention is particularly advantageous is a multi-pixel, linear array of MEMS based two-dimensional (2D) diffractors, such as a Linear Planar Light Valve (PLV^{TM}) commercially available from Silicon Light Machines, Inc., of San Jose, California. A Linear PLV^{TM} will now be described with reference to FIGS. 2A through 2C and FIG. 3.

For purposes of clarity, many of the details of fabricating and operating MEMS based two-dimensional (2D) diffractors, which are widely known and not relevant to the present invention, have been omitted from the following description. MEMS based 2D diffractors are described in greater detail, for example, in commonly assigned U.S. Patent Serial No. 7,064,883, entitled, “Two-Dimensional Spatial Light Modulator,” by Alexander Payne et al., issued on June 20, 2006, and incorporated herein by reference in its entirety.

FIG. 2A illustrates a schematic block diagram of a sectional side view of a 2D modulator or diffractor 200 in a quiescent or un-driven state. Referring to FIG. 2A, the 2D diffractor 200 generally includes a piston layer 202 suspended over a surface of a substrate 204 by posts 206 at corners of the piston layer and/or 2D diffractor. The piston layer 202 includes an electrostatically deflectable piston 202a and a number of flexures 202b through which the piston is flexibly or movably coupled to the posts 206. A faceplate 208 overlying the piston layer 202 includes a first light reflective surface 210 and an aperture or cut-out portion 212 which separates the faceplate from a second reflective surface 214 on or attached to the piston 202a. The second light reflective surface 214 can either be formed directly on the top surface of the piston 202a, or, as in the embodiment shown, on a mirror 216 supported above and separated from the piston 202a by a central post 218 extending from the piston to the mirror. The first and second light reflective surfaces 210, 214, have equal area and reflectivity so that in operation electrostatic deflection of the piston 202a caused by an electrode 220 formed in or on the piston layer 202 and an electrode 222 in the substrate 204 brings light reflected from the first light reflective surface 210 into constructive or destructive interference with light reflected from the second light reflective surface 214.

Generally, the electrode 222 in the substrate 204 is coupled to one of a number drive channels in a drive circuit or driver 224, which can be integrally formed in the substrate adjacent to or underlying the 2D diffractor 200, as in the embodiment shown. The electrode 222 in the substrate 204 can be coupled to the driver 224 through a via extending through the substrate from the driver to the electrode, and the electrode 220 formed in or on the piston layer 202 can be coupled to the driver or an electrical ground through a conductor extending through one of the posts 206 and the piston layer. As explained in greater detail below, typically multiple individual 2D diffractors 200 are grouped or ganged together under control of a single drive channel to function as a single pixel in the multi-pixel, linear array of the SLM.

FIG. 2B is a schematic block diagram of the 2D diffractor 200 of FIG. 2A in an active or driven state, showing the piston 202a deflected towards the substrate 204, and FIG. 2C is a top view of the 2D diffractor of FIGS. 2A and 2B illustrating the static first light reflective surface 210 and the movable second light reflective surface 214.

An exemplary multi-pixel, linear array of dense-packed, MEMS based 2D diffractors will now be described with reference to the block diagram of FIG. 3. FIG. 3 is a planar top view of a SLM 300 including a linear array 301 of 2D diffractors 302, such as those shown in FIGS. 2A-C, grouped or coupled together to a number of drive channels to or pixels.

Referring to FIG. 3, in one embodiment the 2D diffractors 302 are grouped into a linear array 301 of interleaved channels or pixels 304 along a first, horizontal or longitudinal axis 306. Each of the 2D diffractors 302 in a single pixel 304 share a common drive channel or driver 308. Although in the embodiment shown each pixel 304 is depicted as having a single column of 122D diffractors 302 grouped along a transverse or vertical or transverse axis 310 perpendicular to the horizontal or longitudinal axis 306 of the array, this is merely to facilitate illustration of the array. It will be appreciated that each channel or pixel can include any number of 2D diffractors arranged in one or more columns of any length across the width or vertical or transverse axis of the array without departing from the spirit and scope of the invention. For example, in one embodiment of the SLM 300 particularly suited for the spectral shaping systems and methods of the present disclosure, each pixel 304 includes a single column of 40 diffractors grouped along the transverse axis 310 of the array. Similarly, the SLM 300 can include an array 301 of any number of pixels 304 or a number of individual arrays 301 placed end to end adjacent to one another. This later configuration can help to increase power handling of the SLM 300 as the optically active area of the array 301 gets larger by increasing the number of columns of diffractors per pixel. If the damage threshold per diffractor is constant, power handling can be increased proportional to the area increase.

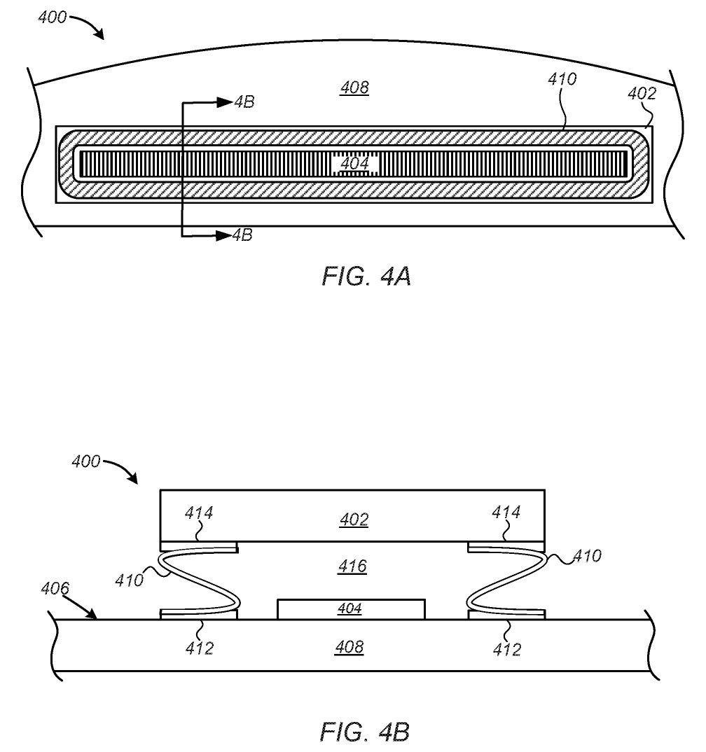

A hermetically sealed wafer level MEMS package for an optical MEMS formed on a substrate will now be described with reference to FIGS. 4A and 4B.

Referring to FIG. 4A, the MEMS package 400 generally includes an optically transparent window 402 overlying an optical MEMS 404 previously formed on a surface 406 of a wafer or substrate 408, and a spacer 410 interposed between the window and the surface of the substrate, and laterally surrounding the optical MEMS. The window 402 can include fused silica, boron-silicate or sapphire (Al₂O₃). Preferably, the window 402 includes fused silica which has been found to exhibit superior optical and mechanical properties when used with a diffractive SLM, such as those described above. Fused Silica includes none of the striations commonly found in glass windows previously used to package optical MEMS thereby providing improved imaging quality. Additionally, fused silica absorbs significantly less heat, which is valuable in many higher power applications in which diffractive SLMs are used, such as thermal printing and additive or subtractive manufacturing.

Optionally, the window can further include an anti-reflective coating (ARC) on at least one of an upper or lower light transmissive surfaces of the window.

The substrate 408 can include any crystalline material suitable for fabricating the optical MEMS and the associated integrated circuits (IC), such as a silicon or gallium-arsenide.

The spacer 410 is made from a material having a coefficient of thermal expansion (CTE) between that of the substrate and window to compensate for CTE mismatch between the window and substrate, and has a lateral cross-section (shown in FIG. 4B) to enable movement between the window and substrate due to differences in thermal expansion without compromising the hermetically sealed cavity. In some embodiments, the spacer 410 is made from a nickel-cobalt alloy, such as Kovar^{TM}, having a coefficient of thermal expansion between that of a silicon substrate 408 and a fused silica window 402. In some embodiments, the spacer 410 includes adhesion promoting layers on a first or lower surface and a second upper attachment-surface to facilitate bonding between the spacer and substrate, and the spacer and window to enable forming the hermetically sealed cavity. Suitable materials for the adhesion promoting layers can include one or more layers of gold (Au), chromium (Cr) and/or nickel (Ni). For example, in one embodiment the adhesion promoting layer includes a thin layer of gold formed or plated onto the first and second attachment-surfaces. In some embodiments, the plating the gold is preceded by forming chromium and/or Ni under layers.

The spacer 410 by increasing the distance between the window 402 and a focal plane or optically active surface of the optical MEMS, allows the window to be angled or tilted (not shown in this figure), eliminating 0^{th} order reflections from the window and providing enhanced contrast. Additionally, the spacer 410 increases volume of sealed cavity 416 reducing undesirable charging and potential caused by condensation on or between optically active surfaces of the optical MEMS and window.

Generally, the MEMS package 400 further includes a first preform 412 between an attachment-surface, of the substrate and a first attachment-surface of the spacer to attach the spacer 410 to the substrate 408, and a second preform 414 between a second attachment-surface of the spacer and an attachment-surface of the window 402 to attach the window to the spacer 410. The MEMS package forms a hermetically sealed cavity 416 enclosing the optical MEMS 404. The first and second preforms 412, 414, can include a bonding material or agent such as solder.

Optionally, the hermetically sealed cavity 416 can be filled with a fill gas selected to facilitate thermal management of the optical MEMS 404 and/or inhibit chemical reactions between optically active surfaces of the optical MEMS and materials of the MEMS package 400. The fill gas can include a mixture of one or more of nitrogen, hydrogen and helium or other inert gases, such as argon, neon, krypton or xenon. For example the fill gas can be a forming gas including a mixture of 80% nitrogen, 10% hydrogen and 10% helium. Alternatively, the fill gas can consist substantially of hydrogen, helium or a mixture of both. In some embodiments, the fill gas pressurizes the hermetically sealed cavity up to about 60 pounds per square inch (PSI).

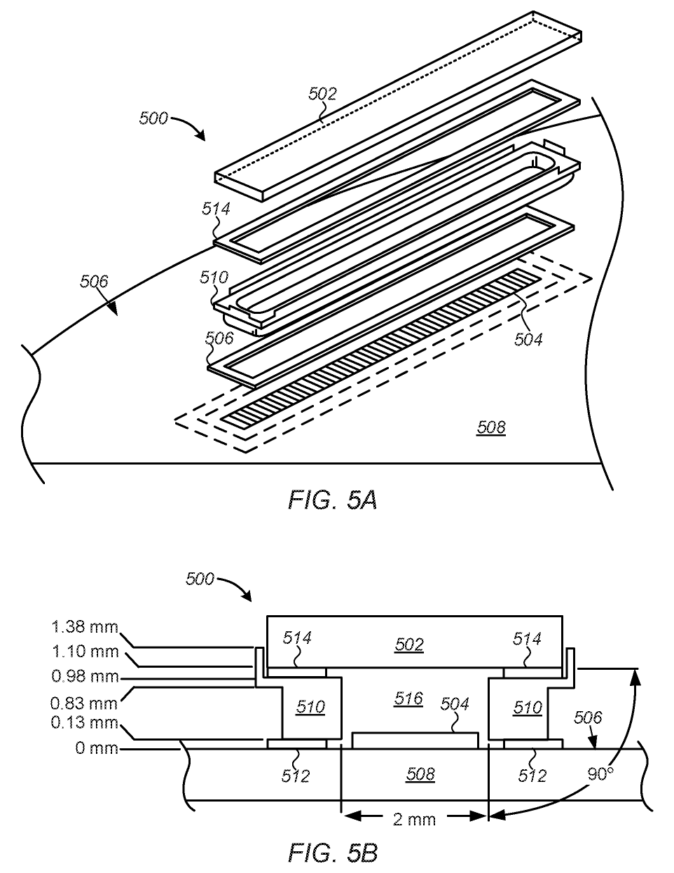

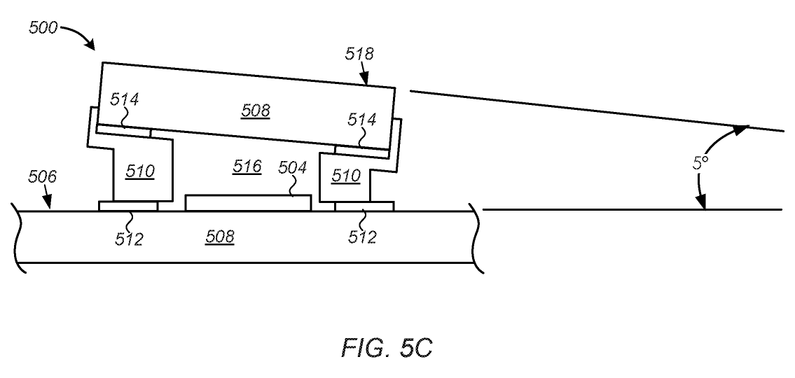

Another embodiment of a wafer level MEMS package for an optical MEMS is shown in FIGS. 5A and 5B, where FIG. 5A is an exploded perspective view of the MEMS package 500, and FIG. 5B is a schematic block diagram of a sectional side view of the MEMS package of FIG. 5A.

As with the generalized embodiment shown and described above with respect to FIGS. 4A and 4B, the MEMS package 500 includes a fused silica window 502 overlying an optical MEMS 504 previously formed on a surface 506 of a silicon substrate 508, and a spacer 510 laterally surrounding the optical MEMS interposed between the window and surface of the substrate. A lower or first attachment-surface of the spacer 510 is bonded or attached to the surface 506 of the substrate 508 by a first preform 512, and an upper or second attachment-surface of the spacer 510 is attached to the window by a second preform 514 to form a hermetically sealed cavity 516.

The material of the window 502 preferably includes fused silica, while the substrate 508 includes a crystalline material such as silicon, and the spacer 510 includes a nickel-cobalt alloy, such as Kovar^{TM}, having a CTE between that of fused silica and silicon, and a shape or configuration to movement to enable movement between the window and substrate due to differences in thermal expansion. In the embodiment, shown in FIG. 5B the spacer 510 has a indented shape in which an upper attachment-surface of the second preform 514 is offset from a lower attachment-surface of the first preform 512, to provide the desired flexibility while maintaining desirably large attachment-surfaces.

Exemplary dimensions for elements of the MEMS package in millimeters (mm) are shown in FIG. 5B.

FIG. 5C is a schematic block diagram of a sectional side view of another embodiment of the wafer level package 500 of FIG. 5A, including a window 502 with an optically transmissive surface 518 tilted or angled at angle of about 5° relative to a surface 506 of the substrate 508. It is note that the angle in FIG. 5C is exaggerated for purposes of illustration.

In the embodiments described above the window includes a fused silica window attached to the substrate through a spacer including a nickel-cobalt alloy, such as Kovar^{TM}. However, it will be understood that the window may alternatively be made of any glass with a flexible spacer made of a material having suitable thermal coefficient of expansion (TCE) match. For example, the window can include a standard boron-silicate glass or sapphire (Al₂O₃) attached to the substrate through thin, flexible spacer including an alloy with a suitable TCE.

A method of fabricating a hermetically sealed wafer level MEMS package for optical MEMS, according to an embodiment of the present disclosure will now be described with reference to the flow chart of FIG. 6.

Referring to FIG. 6 the method begins with integrally fabricating an optical MEMS, including any associated control circuitry on a surface of a substrate (step 602). Next, a first preform is positioned on the surface of the substrate, the first preform laterally surrounding the optical MEMS (step 604). A first attachment-surface of a spacer is positioned on the first preform so that the spacer laterally surrounds the optical MEMS (step 606). A second preform is positioned on a second attachment-surface of the spacer (step 608), and a window positioned on the second preform (step 610). Finally, the window is bonded to the spacer and the spacer is bonded to the surface of the substrate to form a hermetically sealed cavity enclosing the optical MEMS (step 612). Generally, the wafer is then diced or singulated to form a complete packaged optical MEMS (step 602).

As described above the window preferably includes fused silica, while the substrate includes a crystalline material such as silicon, and the spacer includes a nickel-cobalt alloy, such as Kovar^{TM}, having a CTE between that of fused silica and silicon, and a shape or configuration to movement to enable movement between the window and substrate due to differences in thermal expansion.

The material of the first and second preforms can include a eutectic solder, and the step of bonding, step 610, can be accomplished by heating the substrate with the assembled MEMS package positioned thereon to a temperature above the melting point bonding agent or solder sufficient to bond the spacer to the substrate and the window to the spacer. Suitable eutectic materials for the first and second preforms or solder can include, for example, gold.

Optionally or preferably the bonding can be accomplished in an environment, such as a sealed furnace, filled with a fill gas to fill the hermetically sealed cavity. As described above the fill gas can include a forming gas including a mixture of nitrogen, hydrogen and helium or substantially pure hydrogen, helium or a mixture of both. The gas can be p pressurizes the hermetically sealed cavity up to about 60 pounds per square inch (PSI).

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

It is to be understood that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The breadth and scope of the present invention should not be limited by any of the above-described exemplary embodiments, but should be defined only in accordance with the following claims and their equivalents.

What is claimed is:

1. A microelectromechanical system (MEMS) package comprising:
a window overlying an optical MEMS on a surface of a substrate;
a spacer interposed between the window and the surface of the substrate, the spacer laterally surrounding the optical MEMS;
a first preform between an attachment-surface of the substrate and a first attachment-surface of the spacer, attaching the spacer to the substrate; and
a second preform between a second attachment-surface of the spacer and an attachment-surface of the window,
wherein the MEMS package forms a hermetically sealed cavity enclosing the optical MEMS.

2. The MEMS package of claim 1 wherein the window comprises fused silica, boron-silicate glass, or sapphire and the spacer comprises an alloy having a coefficient of thermal expansion (CTE) between that of the substrate and window.

3. The MEMS package of claim 2 wherein the window comprises fused silica, and the spacer comprises a nickel-cobalt alloy or Kovar^{TM}.

4. The MEMS package of claim 2 wherein the spacer comprises a lateral cross-section perpendicular to the surface of the substrate that enables lateral movement between the window and substrate to permit differences in thermal expansion between the window and substrate without compromising the hermetically sealed cavity.

5. The MEMS package of claim 2 wherein the spacer comprises adhesion promoting layers on the first and second attachment-surfaces to facilitate bonding between the spacer and substrate, and the spacer and window to enable forming the hermetically sealed cavity.

6. The MEMS package of claim 5 wherein the adhesion promoting layers comprise a thin layer of gold formed on the first and second attachment-surfaces.

7. The MEMS package of claim 1 wherein the hermetically sealed cavity is filled with a fill gas selected to facilitate thermal management of the optical MEMS and/or inhibit chemical reactions between optically active surfaces of the optical MEMS and materials of the MEMS package.

8. The MEMS package of claim 7 wherein the fill gas pressurizes the hermetically sealed cavity up to 60 pounds per square inch (PSI).

9. The MEMS package of claim 7 wherein the fill gas comprises a mixture of one or more of nitrogen, hydrogen, helium, argon, neon, krypton or xenon.

10. The MEMS package of claim 9 wherein the fill gas is a forming gas comprising a mixture of 80% nitrogen, 10% hydrogen and 10% helium.

11. The MEMS package of claim 9 wherein the fill gas consists of hydrogen, helium or a mixture of both.

12. The MEMS package of claim 1 wherein the spacer is configured to provide an angle between the window and the surface of the substrate to reduce reflection from at least one of an upper or lower light transmissive surfaces of the window.

13. The MEMS package of claim 12 wherein the spacer is configured to provide an angle of 5° between the window and the surface of the substrate.

14. The MEMS package of claim 1 wherein the window comprises an anti-reflective coating (ARC) on at least one of an upper or lower light transmissive surfaces of the window.

15. A method of forming a wafer level package for an optical microelectromechanical system (MEMS), the method comprising:
bonding a spacer to a surface of substrate, the spacer laterally surrounding the optical MEMS on the surface of the substrate; and
bonding a fused silica window to the spacer, the fused silica window overlying the optical MEMS to form a hermetically sealed cavity enclosing the optical MEMS,
wherein the spacer comprises a nickel-cobalt alloy having a coefficient of thermal expansion (CTE) between that of the substrate and window.

16. The method of claim 15 wherein the spacer comprises Kovar^{TM}.

17. The method of claim 15 wherein the spacer comprises a lateral cross-section perpendicular to the surface of the substrate enabling lateral movement between the window and substrate to permit differences in thermal expansion between the window and substrate without compromising the hermetically sealed cavity.

18. The method of claim 15 wherein bonding the spacer to the surface of the substrate and bonding the window to the spacer comprises positioning a first preform between an attachment-surface of the substrate and a first attachment-surface of the spacer, and a second preform between a second attachment-surface of the spacer and an attachment-surface of the, window, wherein the first and second preforms comprise solder and wherein bonding comprises heating the substrate and assembled MEMS package to a temperature above a melting point of the solder to form the hermetically sealed cavity.

19. The method of claim 18 wherein the bonding is performed in an environment to fill the cavity with a fill gas selected to facilitate thermal management of the optical MEMS and/or inhibit chemical reactions between optically active surfaces of the optical MEMS and materials of the MEMS package.

20. The method of claim 18 further comprising forming adhesion promoting layers on the first and second attachment-surfaces of the spacer prior to positioning of the first and second preforms to facilitate bonding between the spacer and substrate, and the spacer and window to enable forming the hermetically sealed cavity.
